(19) United States
(12) Patent Application Publication
(10) Pub. No.: US 2007/0254492 A1
(43) Pub. Date: Nov. 1, 2007

(54) TECHNIQUE FOR FORMING A SILICON NITRIDE LAYER HAVING HIGH INTRINSIC COMPRESSIVE STRESS

(76) Inventors: Steffen Baer, Dresden (DE); Joerg Hohage, Dresden (DE); Volker Kahlert, Dresden (DE)

Correspondence Address: WILLIAMS, MORGAN & AMERSON, 10333 RICHMOND, SUITE 1100, HOUSTON, TX, 77042, US

(21) Appl. No.: 11/610,540

(22) Filed: Dec. 14, 2006

(30) Foreign Application Priority Data
Apr. 28, 2006 (DE) 10 2006 019 881.6

(51) Int. Cl. H01L 21/31

(52) U.S. Cl. 438/778

(57) ABSTRACT

By forming a compressively stressed silicon nitride material on the basis of a mixed frequency plasma-enhanced chemical vapor deposition (PECVD) process, a higher compressive stress may be achieved at a reduced defect rate compared to conventional single frequency processes. Consequently, a more efficient strain-inducing mechanism for P-channel transistors and a corresponding increase of performance may be accomplished.

### BACKGROUND OF THE INVENTION

1. Field of the Invention

Generally, the present invention relates to the field of microstructures, such as integrated circuits, and, more particularly, to the formation of a silicon nitride layer having a high intrinsic compressive stress.

2. Description of the Related Art

The fabrication of microstructures, such as integrated circuits, requires the formation of a large number of circuit elements or other elements on a given chip area according to a specified layout. For this purpose, different types of material layers have to be formed and frequently patterned or otherwise modified to obtain desired material properties in a highly localized manner. For instance, conductive, semiconductive and insulating materials may have to be formed at well-defined locations within a chip area in order to accomplish a desired functional behavior of the element under consideration. Moreover, certain materials are primarily used for enhancing the patterning or modifying process of other materials, such as mask layers, etch stop layers and the like. A well-established and frequently used dielectric material in the fabrication of microstructures is silicon nitride due to its advantageous properties, such as high etch selectivity in a plurality of wet and dry etch processes with respect to silicon, silicon oxide and the like, which are themselves frequently used materials for manufacturing microstructures. For example, silicon nitride is frequently used in combination with silicon dioxide for locally forming dielectric portions, wherein one or the other material may be used as an efficient etch stop layer during a wet or dry etch process. In addition to the many applications of silicon nitride in microstructure technology, recently silicon nitride has also become a viable candidate for enhancing the electrical characteristics of circuit elements, such as transistors and the like, by altering the mobility of charge carriers.

Generally, a plurality of process technologies are currently practiced, wherein, for complex circuitry, such as microprocessors, storage chips and the like, CMOS technology is currently one of the most promising approaches due to the superior characteristics in view of operating speed and/or power consumption and/or cost efficiency. During the fabrication of complex integrated circuits using CMOS technology, millions of complementary transistors, i.e., N-channel transistors and P-channel transistors, are formed on a substrate including a crystalline semiconductor layer. A MOS transistor, irrespective of whether an N-channel transistor or a P-channel transistor is considered, comprises so-called PN junctions that are formed by an interface of highly doped drain and source regions with an inversely doped channel region disposed between the drain region and the source region.

The conductivity of the channel region, i.e., the drive current capability of the conductive channel, is controlled by a gate electrode formed above the channel region and separated therefrom by a thin insulating layer. The conductivity of the channel region, upon formation of a conductive channel due to the application of an appropriate control voltage to the gate electrode, depends on the dopant concentration, the mobility of the majority charge carriers, and, for a given extension of the channel region in the transistor width direction, on the distance between the source and drain regions, which is also referred to as channel length. Hence, in combination with the capability of rapidly creating a conductive channel below the insulating layer upon application of the control voltage to the gate electrode, the conductivity of the channel region substantially determines the performance of the MOS transistors. Thus, the reduction of the channel length, and associated therewith the reduction of the channel resistivity, renders the channel length a dominant design criterion for accomplishing an increase in the operating speed of the integrated circuits.

The reduction of the transistor dimensions, however, raises a plurality of issues associated therewith that have to be addressed so as to not unduly offset the advantages obtained by steadily decreasing the channel length of MOS transistors. One problem in this respect is the development of enhanced photolithography and etch strategies to reliably and reproducibly create circuit elements of critical dimensions, such as the gate electrode of the transistors, for a new device generation. Moreover, highly sophisticated dopant profiles, in the vertical direction as well as in the lateral direction, are required in the drain and source regions to provide low sheet and contact resistivity in combination with a desired channel controllability.

Since the continuous size reduction of the critical dimensions, i.e., the gate length of the transistors, necessitates the adaptation and possibly the new development of process techniques concerning the above-identified process steps, it has been proposed to enhance device performance of the transistor elements by increasing the charge carrier mobility in the channel region for a given channel length. One efficient approach is the modification of the lattice structure in the channel region, for instance by creating tensile or compressive strain, which results in a modified mobility for electrons and holes. For example, creating tensile strain in the channel region increases the mobility of electrons, while compressive strain in the channel region may increase the mobility of holes, thereby providing the potential for enhancing the performance of P-type transistors.

One promising approach is the creation of stress in the insulating layer, which is formed after the formation of the transistor elements to embed the transistors and which receives metal contacts to provide the electrical connection to the drain/source regions and the gate electrode of the transistors. Typically, this insulation layer comprises at least one etch stop layer, typically formed of silicon nitride, and a further dielectric layer, such as silicon dioxide, that may be selectively etched with respect to the etch stop layer. In order to obtain an efficient stress transfer mechanism to the channel region of the transistor for creating strain therein, the silicon nitride layer may be provided with a high intrinsic stress, wherein, in particular, a high compressive stress may be desired to efficiently enhance the performance of P-channel transistors, which may have, in typical configurations, a reduced drive current capability due to the reduced charge carrier mobility of holes relative to electrons. Typically, during the formation of advanced integrated circuits, silicon nitride layers provided at a late manufacturing stage are formed on the basis of plasma enhanced chemical vapor deposition (PECVD) techniques, since elevated temperatures, as may be required for thermal chemical vapor deposition (CVD), may adversely affect the transistor elements. For instance, the metal silicide regions, typically formed in drain and source regions, may not tolerate unduly high temperatures. Moreover, using a plasma-based deposition technique provides the possibility of adjusting the degree of ion bombardment during the deposition of the silicon nitride, which is one efficient process parameter in controlling the amount of compressive stress obtained. The degree of ion bombardment may be conventionally adjusted by the amount of high frequency (HF) power supplied to the deposition atmosphere, which leads to ionization of precursor particles and results in charging the substrate to be coated, thereby also generating the desired degree of acceleration of the ions towards the charged substrate surface. It turns out, however, that increasing the HF power for enhancing the degree of ion bombardment and thus the amount of intrinsic compressive stress in the silicon nitride layer may also result in an increased degree of particle contamination of the layer as deposited. Thus, the increased particle contamination may lead to an overall increased defect rate in the further processing of the device, thereby rendering conventional PECVD techniques for forming silicon nitride layers with high compressive stress less attractive.

In view of the above-described situation, there exists a need for an improved technique that enables the creation of intrinsic compressive stress in a silicon nitride layer while avoiding or at least reducing one or more of the above identified problems.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present invention is directed to a technique for forming a silicon nitride material having a high intrinsic compressive stress on the basis of a PECVD process, wherein the deposition atmosphere may be controlled on the basis of high-frequency power and low-frequency power so as to obtain the desired target compressive stress while significantly reducing the defect rate of the silicon nitride as deposited. By establishing the deposition atmosphere and thus the acceleration potential for increasing the ion bombardment during the deposition phase on the basis of a low-frequency power, significantly increased amounts of compressive stress may be obtained compared to conventional techniques, which substantially rely on a single frequency excitation and biasing power, which may cause an increased defect rate at stress levels above 1.5 GPa. Consequently, upon forming silicon nitride material on the basis of low-frequency power, an enhanced stress transfer mechanism for P-channel transistors may be provided, thereby significantly enhancing the drive current capability of these transistors.

According to one illustrative embodiment of the present invention, a method comprises establishing a plasma in a silane-containing deposition atmosphere on the basis of high-frequency power and low-frequency power. The method further comprises adjusting a degree of ion bombardment towards a deposition surface of a substrate by controlling at least one of the high-frequency power and the low-frequency power. Finally, silicon nitride is deposited on the deposition surface, wherein the silicon nitride comprises an intrinsic compressive stress.

According to another illustrative embodiment of the present invention, a method comprises forming a transistor element having a gate electrode structure above a substrate. Moreover, a compressively stressed silicon nitride material is formed near the gate electrode structure on the basis of a plasma-based silane-containing deposition atmosphere. The method further comprises controlling an amount of the compressive stress at least on the basis of an amount of high-frequency power and an amount of low-frequency power supplied to the deposition atmosphere.

### BRIEF DESCRIPTION OF THE DRAWINGS

The invention may be understood by reference to the following description taken in conjunction with the accompanying drawings, in which like reference numerals identify like elements, and in which:

FIG. 1a schematically illustrates a cross-sectional view of a semiconductor device during a plasma enhanced chemical vapor deposition process for forming a silicon nitride layer having a high intrinsic compressive stress according to illustrative embodiments of the present invention;

FIG. 1b schematically illustrates a deposition system appropriate for establishing a silane-based deposition atmosphere with high-frequency power and low-frequency power in accordance with illustrative embodiments; and

FIGS. 2a-2d schematically illustrate cross-sectional views of a semiconductor device including a transistor element during various manufacturing stages, at least in one of which a compressively stressed silicon nitride material is formed on the basis of a technique described with reference to FIGS. 1a-1b.

While the invention is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION OF THE INVENTION

Illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present invention will now be described with reference to the attached figures. Various structures, systems and devices are schematically depicted in the drawings for purposes of explanation only and so as to not obscure the present invention with details that are well known to those skilled in the art. Nevertheless, the attached drawings are included to describe and explain illustrative examples of the present invention. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present invention contemplates a technique for the formation of compressively stressed silicon nitride on the basis of a plasma enhanced chemical vapor deposition (PECVD) technique, in which process parameters may be controlled so as to obtain a high amount of intrinsic compressive stress while nevertheless a corresponding particle contamination and thus defect rate may be reduced compared to conventional approaches. As is generally known, during the deposition of silicon nitride material on the basis of chemical vapor deposition (CVD), process parameters, such as deposition pressure, temperature and the like, may be appropriately controlled in order to provide a desired high amount of compressive stress. In particular, the degree of ion bombardment during the deposition process may significantly affect the stress characteristics of the resulting silicon nitride film, since the ion bombardment during the deposition may affect the resulting silicon/nitrogen and silicon/hydrogen bondings, which may finally lead to a certain degree of stress in the silicon nitride material. Generally, by increasing the degree of ion bombardment during the deposition, the amount of intrinsic compressive stress for otherwise identical process parameters may be increased. In conventional techniques, the degree of ion bombardment, which is substantially determined by a resulting accelerating voltage between ionized particles and the substrate surface to be coated, is adjusted on the basis of the high-frequency power that is usually coupled into the precursor gases by inductive or capacitive coupling from a corresponding high frequency generator. Without intending to restrict the present invention to the following explanation, it is nevertheless believed that the high-frequency biased substrate surface may still maintain some electrical charge even after switching off the plasma, i.e., switching off the high-frequency power supply, which may lead to a further deposition of unwanted particles, thereby significantly enhancing the defect rate, in particular, when a high level of high-frequency power may have to be used to generate the required high degree of ion bombardment. Contrary to this conventional approach, in the present invention, an additional low-frequency power is supplied in order to significantly enhance the ion bombardment while substantially reducing the adverse effects of the high-frequency power on the substrate surface. In this respect, it should be appreciated that the terms “high-frequency power” and “low-frequency power” are to be understood with respect to the involved frequencies such that the frequency of the high-frequency power is significantly higher than the frequency of the low-frequency power, wherein typically the high-frequency power involves a frequency range from several MHz to several tens of MHz, for example approximately 10-20 MHz, for instance approximately 13-14 MHz, including a typical high-frequency value of approximately 13.56 MHz, while in this application the term low-frequency power may include frequencies from several MHz, typically several hundred KHz, down to a DC power. In one illustrative embodiment, the low-frequency range comprises 0 Hz to 500 KHz, for example approximately 100-200 KHz. Consequently, by using excitation power modulated by at least two significantly different frequencies, compressive silicon nitride layers may be formed having an intrinsic compressive stress of approximately 2 GPa and even higher while at the same time providing a defect rate that is comparable to conventional techniques with significantly reduced intrinsic stress. As a consequence, the technique as provided by the present invention is highly advantageous during the formation of any microstructures, in which highly compressive silicon nitride material is required and hence the present invention should not be restricted to any specific application of compressively stressed silicon nitride, unless such restrictions are explicitly set forth in the appended claims and the following detailed description.

In other illustrative embodiments, a highly compressive silicon nitride material having a low defect rate may be used in combination with advanced transistor elements in order to create a desired type of strain in a channel region of a transistor, as will be described later on in more detail.

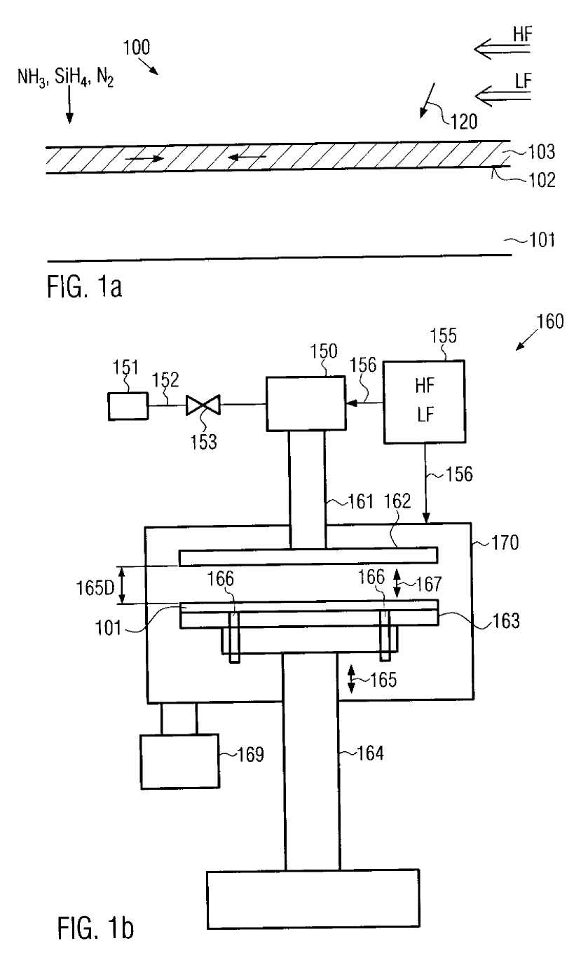

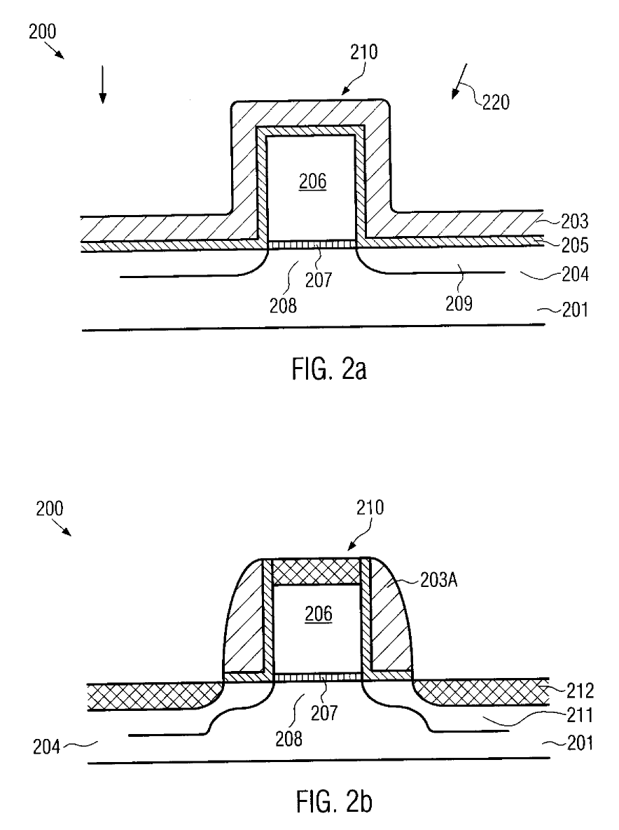

With reference to the drawings, further illustrative embodiments of the present invention will now be described in more detail. FIG. 1a schematically illustrates a cross-sectional view of a semiconductor device 100 during the deposition of a compressively stressed silicon nitride material. The semiconductor device 100 may represent any microstructure, such as an integrated circuit, a micromechanical device, an opto-electronic device and the like, in which the provision of a highly compressively stressed silicon nitride material may be required. The device 100 may comprise a substrate 101, which may be represented by any substrate appropriate for the formation of corresponding microstructure features thereon and therein. The substrate 101 may comprise a surface 102, on which is formed a silicon nitride material 103, which may be provided in the form of a layer having a specified thickness according to device requirements. It should be appreciated that the surface 102 may have any appropriate topography, depending on previous process steps that may have been performed in order to provide microstructure features on and in the substrate 101.

The substrate 101 including the surface 102 and possibly including any structure elements, such as circuit elements and the like, may be formed on the basis of well-established process techniques for the formation of microstructures, wherein the corresponding process steps may include photolithographic patterning, etch processes, implantation processes, deposition processes and the like. Thereafter, the device 100 may be exposed to a deposition atmosphere 120, which in one illustrative embodiment comprises silane (SiH₄), in order to form the silicon nitride material 103. In other illustrative embodiments, the deposition atmosphere 120 may be established, in addition to silane, on the basis of ammonia (NH₃) and nitrogen as further precursors or carrier gases, wherein, in one illustrative embodiment, further significant amounts of other carrier gases, such as argon, may not be required thereby reducing the process complexity for establishing and controlling the deposition atmosphere 120. In establishing the deposition atmosphere 120, the temperature of the substrate 101 and thus of the respective deposition surface 102 may also be adjusted to an appropriate range, wherein in some illustrative embodiments the respective temperature of the substrate 101 is maintained at 500° C. and less, for example 500° C. to 300° C., while in other illustrative embodiments the temperature is adjusted to approximately 400° C. Maintaining the temperature of the substrate 101 at a temperature range as specified above may reduce adverse effects of the temperature on previously formed microstructural features and materials, as will be described later on in more detail when it is referred to the formation of a transistor element. Moreover, the deposition atmosphere 120 may be established in a low pressure ambient, wherein the pressure may be controlled so as to be within a range of approximately 0.8-2.0 Torr, when a distance of ionized particles moving towards the surface 102 is in the range of approximately 200-400 mils (1 mil=0.0254 mm). In other cases, if significantly longer distances may be selected for an average path length of ionized particles, the corresponding pressure may be reduced in order to maintain scattering events at a moderately low level.

After establishing the deposition atmosphere 120 on the basis of silane, the actual deposition of silicon nitride material may be initiated by supplying high-frequency power (HF) and low-frequency power (LF) to the deposition atmosphere 120, thereby establishing the required plasma ambient and also generating an appropriate voltage between the atmosphere 120 and the substrate surface 102, which provides a high degree of directionality of the ionized particles moving to the surface 102. Consequently, a high degree of ion bombardment during the formation of the silicon nitride material 103 is generated, which in turn provides the desired high degree of intrinsic compressive stress. Since the low-frequency power may have a significantly increased “wavelength” compared to the high-frequency power, for example up to 2 orders of magnitude or more, a highly efficient creation of an acceleration voltage is achieved, while the high frequency biased excitation of the surface 102 may be reduced. As a consequence, during the ongoing deposition of the material 103, the high degree of ion bombardment ensures the generation of a high compressive stress, while after discontinuing the supply of high-frequency power and low-frequency power, an additional deposition of unwanted particles may be significantly reduced.

In one illustrative embodiment, the amount of high-frequency power supplied to the atmosphere 120 is less than the amount of low-frequency power during the entire deposition phase, thereby providing a high degree of ion bombardment while reducing adverse effects of the high-frequency modulated power. It should be appreciated that the absolute amount of high-frequency power and low-frequency power supplied to the deposition atmosphere 120 may depend on the configuration of a respective deposition reactor or chamber and corresponding values may be readily established on the basis of the above teaching and the one or more further illustrative embodiments described with reference to FIG. 1b, in which a typical representative PECVD deposition tool may be described.

After the discontinuation of the supply of high-frequency power and low-frequency power, further purge and pump processes may be performed in order to remove any unwanted byproducts created during the preceding deposition in the atmosphere 120, and thereafter the further processing may be continued on the basis of process and device requirements. Consequently, due to the effective control of the ion bombardment within the deposition atmosphere 120 on the basis of the low-frequency power, a high compressive stress in the material 103 may be obtained, wherein, in addition to a low defect rate, a reduced process time compared to conventional approaches may also be achieved, in which the ion bombardment is substantially adjusted on the basis of a high amount of high-frequency power.

With reference to FIG. 1b, a further illustrative embodiment for the formation of a compressively stressed silicon nitride material will be described with reference to a typical configuration of a CVD tool, as may be used for the formation of silicon nitride layers in the fabrication of microstructures.

FIG. 1b schematically illustrates a CVD system 160 that is appropriate for PECVD processes for forming compressively stressed silicon nitride material, such as the material 103 of FIG. 1a. The system 160 may comprise a process chamber 170 including coupling means (not shown) for receiving high-frequency power and low-frequency power, while in other cases a remote reactor 150 may be coupled to the process chamber 170 by a supply line 161, which may have a length and a diameter appropriate for feeding gas from the remote reactor 150 to the process chamber 170. In the process chamber 170, a first plate 162 may be provided and may be adapted to receive and distribute gases supplied thereto. For instance, a correspondingly configured plate may sometimes be referred to as showerhead. For the sake of clarity, any supply lines necessary for feeding gases during a deposition process is not depicted in FIG. 1b. The first plate 162 may also be configured to serve as an electrode to establish a corresponding bias voltage within the process chamber 170. Spaced apart from the first plate 162 and in an opposing relationship, a second plate 163 may be provided that may be coupled to a drive mechanism 164 for vertically moving the second plate 163, as is indicated by the arrow 165. The second plate 163 may be adapted to support a substrate, such as the substrate 101, during the deposition process and may also include a heater assembly (not shown) with which the second plate 163 and thus the substrate 101 may be maintained at a required temperature. The second plate 163 may include a plurality of lift pins 166 that are moveably attached to the second plate 163 and may be moved from a first position or receive position, at which the lift pins 166 are at least partially exposed to a second position or operating position, in which the lift pins 166 are countersunk, i.e., are substantially flush with the upper surface of the second plate 163. Moving the lift pins 166 from the first position into the second position and vice versa is indicated by the arrow 167. For the sake of simplicity, a corresponding mechanism for moving the lift pins 166 is not shown in FIG. 1b.

The remote reactor 150 may be connected to a source of precursor gases 151 via a supply line 152, which may include appropriate valve assemblies 153 for controlling a flow rate of the precursor gases. For instance, as previously explained, in one illustrative embodiment, precursor gases may include silane, ammonia and nitrogen. Moreover, the remote reactor 150 may be coupled to an appropriate excitation unit 155, wherein the coupling is indicated by arrows 156 which may represent an appropriate coupling mechanism to be used depending on the type of excitation unit used. An appropriate excitation unit, such as a high-frequency generator, may be provided in order to create a plasma within the remote reactor 150 and also to provide a desired accelerating voltage between the first plate 162 and the surface of the substrate 101. In other cases, the high-frequency power may be coupled into the chamber 170, while the reactor 150 may act as a gas supply. For example, the coupling 156 may be accomplished by inductive coupling or capacitive coupling for supplying the high-frequency power for the excitation of the precursor gases. Similarly, the low-frequency power may be coupled into the process chamber 170 by inductive coupling or capacitive coupling or by an ohmic contact to the first and second plates 162, 163, when a DC or very low-frequency power is used. Furthermore, the process chamber 170 may be connected to a pump source 169 that is adapted to controllably establish a predefined pressure within the process chamber 170 in order to provide the required environmental conditions for a respective deposition atmosphere, such as the atmosphere 120 as described with reference to FIG. 1a.

During operation of the system 160, the substrate 101 may be loaded onto the plate 163 by means of any appropriate loading system, such as a robotic arm and the like, wherein the lift pins 166 may be appropriately positioned to receive the substrate 101 and to attach the substrate to the plate 163. Moreover, after receiving the substrate 101, the plate 163 may be appropriately positioned by the drive assembly 164, as indicated by the arrow 165, in order to obtain a desired distance 165D with respect to the plate 162. In some illustrative embodiments, the distance 165D may be maintained constant throughout the subsequent processing of the substrate 101, i.e., during a setup phase, an actual deposition phase and a subsequent purge and pump phase, thereby reducing the control complexity and also reducing the cycle time of the deposition process. For example, the system 160 may represent a single chamber CVD system configured for the processing of 200 mm substrates, as is for instance available from Applied Materials Inc under the name “Producer system.” In this case, the distance 165D may be adjusted within a range of 200-400 mils, depending on the selected chamber pressure and the amount of high-frequency power and low-frequency power supplied to the respective deposition atmosphere 120, since these parameters may significantly affect the kinematic behavior of the ionized particles when moving from the first plate 162 to the substrate 101.

For the above-specified configuration of the system 160, the deposition atmosphere 120 may be established on the basis of silane, ammonia and nitrogen with flow rates of approximately 10-80 sccm (standard cubic centimeters per minute), 0-70 sccm and 500-2000 sccm, respectively. The pressure within the deposition atmosphere 120 may be maintained within a range of approximately 0.8-2.0 Torr, while the distance 165D may be maintained within the above-specified range of approximately 200-400 mils. With a substrate temperature of less than 500° C., for instance of approximately 400° C., the actual deposition of silicon nitride material may be initiated by supplying high-frequency power of approximately 20-100 Watts and a low-frequency power of approximately 60-100 Watts. For the above-specified tool configuration, the high-frequency power may involve a frequency of 13-14 MHz while the low-frequency power may be provided with a frequency range of several hundred KHz. While adjusting one of the process parameters, such as flow rates, pressure, distance, temperature, high-frequency power and low-frequency power, the degree of compressive stress in the silicon nitride material, such as the layer 103, may be appropriately adjusted. For instance, for a temperature of approximately 400° C. and a pressure of approximately 1.4 Torr, a distance of approximately 290 mils, and flow rates for silane, ammonia and nitrogen, respectively, of approximately 50 sccm, 40 sccm and 1200 sccm, a compressive stress of approximately 2 GPa may be obtained. On the basis of the above-specified parameter value ranges, the corresponding compressive stress may be varied from approximately 1.5 GPa to approximately 2.5 GPa, wherein, for instance, in some illustrative embodiments, the high-frequency power and/or the low-frequency power may be varied while the other process parameters may be substantially maintained constant. Consequently, a highly efficient control mechanism with reduced complexity may be accomplished, while nevertheless providing increased levels of compressive stress.

The actual deposition phase may be preceded by a respective setup step in which the required gas components may be supplied to the process chamber 170 or the remote reactor, depending on the configuration, on the basis of a desired pressure, while also the respective distance 165D may be adjusted and the temperature of the substrate 101 may be reached. For example, a setup time for establishing the deposition atmosphere 120 may range from approximately 8-12 seconds. Thereafter, the actual deposition phase may be initiated by supplying the low-frequency power and the high-frequency power, wherein, for the above presented parameter ranges, a deposition time of approximately 21-28 seconds may result in a layer thickness of approximately 50 nm. After the deposition, the process chamber 170 may be purged, for instance on the basis of nitrogen, which may be accomplished by discontinuing the supply of the precursor gases silane and ammonia. In one illustrative embodiment, the flow rate of nitrogen as specified above may be maintained during this purge step. For example, under these conditions, a purge time of approximately 5 seconds may be appropriate, wherein the distance 165D as well as the temperature of the substrate 101 may be maintained at the same values as previously used for the actual deposition. Thereafter, a pump step may be performed, for instance for approximately 10 seconds, in order to efficiently remove gaseous components from the chamber 170.

It should be appreciated that although a specific design of the deposition system 160 is described with reference to FIG. 1b, for which specific parameter ranges are given, corresponding parameter values may be readily established on the basis of the above teaching for other configurations of respective PECVD systems.

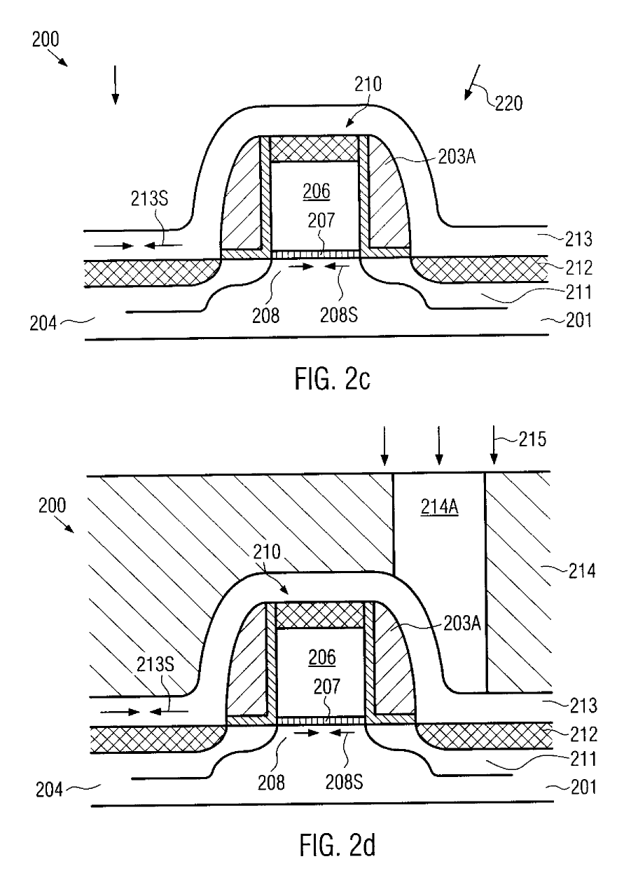

With reference to FIGS. 2a-2d, further illustrative embodiments of the present invention will now be described in more detail in which a compressively stressed silicon nitride film is used for increasing the performance of a transistor element. For this purpose, the stressed silicon nitride material may be formed in the vicinity of a channel region of a transistor element in order to induce a respective compressive strain therein, thereby increasing the drive current capability due to an enhanced hole mobility. For this purpose, a respective compressively stressed silicon nitride material may be used during the formation of spacer elements and/or for the formation of a contact etch stop layer, which is formed above a transistor element typically in combination with an interlayer dielectric material, prior to forming any metallization layers above the transistor element.

FIG. 2a schematically illustrates a semiconductor device 200 which may comprise a substrate 201. The substrate 201 may represent any appropriate substrate having formed thereon a semiconductor layer 204 that is suitable for the formation of transistor elements, such as a P-channel field effect transistor 210. For example, the substrate 201 and the semiconductor layer 204, which may represent a silicon-based semiconductor layer, may in combination define a “bulk” transistor configuration wherein the semiconductor layer 204 may represent an upper portion of the substrate 201, while in other embodiments the substrate 201 in combination with the layer 204 may constitute a silicon-on-insulator (SOI) configuration, wherein a buried insulating layer (not shown) may be provided on the substrate 201 so as to form an interface with the semiconductor layer 204. In this manufacturing stage, the P-channel transistor 210 may comprise a gate electrode 206 formed above the semiconductor layer 204 and separated therefrom by a gate insulation layer 207, which may be comprised of silicon dioxide, silicon nitride, combinations thereof and the like. For instance, in highly advanced devices, a thickness of the gate insulation layer 207 may range from approximately several nanometers to 1.5 nanometers, while a length of the gate electrode 206, that is, the horizontal extension thereof in FIG. 2a, may be approximately 100 nm and significantly less, or even approximately 50 nm and significantly less. Moreover, adjacent to the gate electrode 206 and within the semiconductor layer 204, an implantation region 209 may be formed which may act as extensions of drain/source regions still to be formed. Furthermore, an etch stop layer 205 followed by a silicon nitride layer 203 may be formed above the transistor 210.

The semiconductor device 200 as shown in FIG. 2a may be formed on the basis of well-established process techniques including the deposition of a dielectric layer and a gate electrode material followed by a respective advanced patterning process on the basis of well-established photolithography and etch techniques in order to form the gate electrode 206 and the gate insulation layer 207. Thereafter, an implantation process may be performed in order to create the extension regions 209, wherein it should be appreciated that other strain-inducing mechanisms, such as the provision of strained semiconductor material in the layer 204, may have been performed depending on the process requirements. Next, the etch stop layer 205, for instance comprised of silicon dioxide, may be deposited on the basis of well-established recipes followed by the formation of the spacer layer 203, which in one illustrative embodiment may be comprised of compressively stressed silicon nitride. In this case, a plasma-enhanced deposition process on the basis of a respective deposition atmosphere 220 may be employed, wherein the deposition atmosphere 220 may be established on the basis of the same principles as previously described with respect to the deposition atmosphere 120. That is, if a high compressive stress is desired for the spacer layer 203, the atmosphere 220 may be established on the basis of high-frequency power and low-frequency power in order to obtain a high degree of ion bombardment during the deposition, while reducing the creation of particle contamination during the deposition process. Thus, during the deposition on the basis of the atmosphere 220, the spacer layer 203 may be deposited with a desired degree of compressive stress and with a required thickness corresponding to a width of respective spacer elements to be formed from the spacer layer 203. It should be appreciated that after the deposition of the layer 203, when comprising a high degree of compressive stress, corresponding portions of the layer 203 which are to exhibit a significantly reduced compressive stress, a local stress relaxation may be performed, for instance on the basis of a respective ion implantation on the basis of heavy inert ions, such as xenon and the like.

FIG. 2b schematically illustrates the semiconductor device 200 in a further advanced manufacturing stage. The device 200 comprises a spacer element 203A, which in one illustrative embodiment may be comprised of silicon nitride material having a high intrinsic compressive stress, while in still other illustrative embodiments when high compressive stress of the spacer elements 203A is not desired, the spacer layer 203 as shown in FIG. 2a may be formed in accordance with conventional techniques in order to provide tensile stress or a reduced compressive stress. Furthermore, respective deep drain and source regions 211 are formed in the semiconductor layer 204 and metal silicide regions 212 may be formed in the drain and source regions 211 and in the gate electrode 206.

The device 200 as shown in FIG. 2b may be formed on the basis of the following processes. First, the spacer layer 203 may be patterned on the basis of anisotropic etch recipes, wherein the etch stop layer 205 may be used for reliably stopping the etch process. Thereafter, a further implantation sequence may be performed for creating the drain and source regions 211 on the basis of the respective spacer elements 203A, wherein it should be appreciated that in other illustrative embodiments, when a more sophisticated lateral dopant profile is required, additional spacer elements may be formed on the basis of processes as previously described with respect to the spacer 203A. Thereafter, appropriate anneal processes may be performed for activating the dopants in the regions 211 and/or 209 and for re-crystallizing implantation-induced damage. Thereafter, a silicidation process may be performed to commonly or independently create the metal silicide regions 212 in the drain and source regions 211 and the gate electrode 206, wherein, in sophisticated applications, highly conductive refractory metals, such as nickel, nickel platinum and the like, may be used. If nickel silicide is incorporated in the region 212, a significant instability of this material may occur at temperatures of approximately 450° C., which may have an adverse influence on the overall electrical characteristics of the transistor 210. Consequently, during the further processing, in some embodiments, process temperatures may be kept at or below approximately 450° C. in order to not unduly compromise the characteristics of the respective metal silicide regions 212.

FIG. 2c schematically illustrates the semiconductor device 200 in a further advanced manufacturing stage in which the device is exposed to a deposition ambient for depositing a compressively stressed silicon nitride material 213, wherein the deposition atmosphere may have substantially the same characteristics as previously described with respect to the atmosphere 220 and 120. Hence, based on appropriately selected process parameters and using at least two different modulation frequencies for power supplied to the deposition atmosphere 220, a high degree of compressive stress may be obtained. For instance, as previously described with reference to FIGS. 1a and 1b, a compressive stress having a magnitude of approximately 1.5-2.5 GPa, for instance approximately 2.0 GPa and higher, may be achieved while a low particle contamination may still be maintained. Consequently, due to the respective compressive stress 213S, a respective moderately high strain 208S is induced in the channel region 208 thereby increasing the charge carrier mobility, i.e., the hole mobility, and thus enhancing the drive current capability.

FIG. 2d schematically illustrates the semiconductor device 200 in a further advanced manufacturing stage in which an interlayer dielectric material 214, for instance comprised of silicon dioxide, may be formed above the layer 213. Furthermore, a respective opening 214A may be formed in the material 214 on the basis of a respective anisotropic etch process 215, during which, in some illustrative embodiments, the silicon nitride layer 213 may act as an etch stop layer. Thereafter, a further etch process may be carried out to form a respective opening in the layer 213 in order to contact one or more of the metal silicide regions 212. It should be appreciated that, in highly advanced applications, other strain-inducing sources in addition to the silicon nitride layer 213 and possibly the spacers 203A may be provided, such as embedded strained semiconductor material in the drain and source regions 211. Furthermore, it may be appreciated that the silicon nitride layer 213 may be locally formed above the transistor 210 in order to enhance the hole mobility in the respective channel region 208, whereas the layer 213 may locally be modified or removed, for instance above N-channel transistors, in order to reduce or eliminate any adverse influence on these transistors. It should further be appreciated that the layer 213 may be formed in combination with one or more other thin dielectric etch stop layers, which may be provided below and/or above the silicon nitride layer 213, for instance in the form of respective silicon dioxide liners, in order to enhance the overall process for forming stressed layers having a different type of intrinsic stress and/or for enhancing the patterning process for forming respective contact openings in the material 214 and the layer 213.

As a result, the present invention provides a technique that enables the formation of a highly compressively stressed silicon nitride material on the basis of a PECVD process, in which high-frequency power and low-frequency power are supplied to the respective deposition atmosphere in order to significantly enhance the ion bombardment during deposition, while maintaining particle contamination at a low level. Thereby, the required high-frequency power may be reduced significantly compared to conventional approaches in which the degree of ion bombardment is substantially controlled on the basis of the amount of high-frequency power. Hence, in some illustrative embodiments, the low-frequency power may be provided with a higher amount compared to the high-frequency power, thereby effectively enhancing the ion bombardment while significantly reducing any adverse effects of high frequency biasing of the substrate surface. Moreover, the concept of the present invention may be readily implemented into standard CVD tools without requiring significant modifications, thereby providing the potential for using the respective deposition tool for single frequency processes, when standard recipes are required, while also performing double frequency processes for enhanced levels of compressive stress. Since the reduced effect of high-frequency power may also enable a reduced time interval for setting up the respective deposition atmosphere and for purging and pumping the process chamber after the deposition, even a reduced cycle time may be achieved while additionally the control complexity may also be reduced as, for instance, a fixed spacing may be used during the entire process sequence. The new technique may be efficiently used in combination with manufacturing of advanced P-channel transistors wherein a corresponding silicon nitride layer, such as a contact etch stop layer, may be formed above the respective transistor element in order to significantly increase the compressive strain in the respective channel region. Furthermore, in addition or alternatively, one or more spacer elements may be formed on the basis of a highly compressively stressed silicon nitride material so as to even further enhance the strain-inducing mechanism. By way of example, for otherwise identical device parameters, a P-channel transistor, such as the transistor 210 as shown in FIG. 2d, having formed thereabove a stressed silicon nitride layer, such as the layer 213 formed in accordance with the principles of the present invention, i.e., having a high compressive stress of approximately 2.0 GPa or higher obtained on the basis of a mixed frequency deposition process, resulted in a drive current increase of 3-4% compared to a device having a conventionally formed compressive silicon nitride layer, while a corresponding ring oscillator frequency, i.e., a ring oscillator comprising a plurality of transistor elements, may be achieved that is approximately 2% higher than the corresponding frequency of conventional devices. Consequently, a significant improvement in performance of respective P-channel transistors may be accomplished, while additionally in some illustrative embodiments a reduced cycle time provides an enhanced throughput.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
establishing a plasma in a silane-containing deposition atmosphere on the basis of high-frequency power and low-frequency power;
adjusting a degree of ion bombardment towards a deposition surface of a substrate by controlling at least one of said high-frequency power and said low-frequency power; and
depositing silicon nitride with intrinsic compressive stress on said deposition surface.

2. The method of claim 1, wherein an amount of said low-frequency power is higher than an amount of said high-frequency power.

3. The method of claim 2, wherein a temperature of said substrate is maintained at a temperature of approximately 500° C. or less.

4. The method of claim 3, wherein the temperature is maintained at approximately 400° C.

5. The method of claim 1, wherein a pressure in said deposition atmosphere is in a range of approximately 2.0 Torr to 0.8 Torr.

6. The method of claim 1, wherein said silane-containing deposition atmosphere is established on the basis of silane, ammonia and nitrogen.

7. The method of claim 2, further comprising varying said amount of said high-frequency power and said amount of said low-frequency power so as to maintain said intrinsic compressive stress in a range of approximately 1.5 GPa and 2.5 GPa.

8. The method of claim 1, further comprising forming a transistor element above said substrate prior to depositing said silicon nitride.

9. The method of claim 8, wherein forming said transistor element comprises forming at least one spacer element by depositing a silicon nitride layer and patterning said silicon nitride layer, wherein said silicon nitride layer is deposited within a plasma-based deposition atmosphere established on the basis of high-frequency power and low-frequency power.

10. A method, comprising:
forming a transistor element having a gate electrode structure above a substrate;
forming a compressively stressed silicon nitride material near said gate electrode structure on the basis of a plasma-based silane-containing deposition atmosphere; and
controlling an amount of said compressive stress at least on the basis of an amount of high-frequency power and an amount of low-frequency power supplied to said deposition atmosphere.

11. The method of claim 10, wherein said amount of high-frequency power is less than said amount of low-frequency power.

12. The method of claim 11, wherein a temperature of said substrate is maintained at a temperature of approximately 500° C. or less.

13. The method of claim 12, wherein the temperature is maintained at approximately 400° C.

14. The method of claim 10, wherein a pressure in said deposition atmosphere is in a range of approximately 0.8 Torr to 2.0 Torr.

15. The method of claim 10, wherein said silane-containing deposition atmosphere is established on the basis of silane, ammonia and nitrogen.

16. The method of claim 11, further comprising varying said amount of said high frequency power and said amount of said low frequency power so as to maintain said intrinsic compressive stress in a range of approximately 1.5 GPa to 2.5 GPa.

17. The method of claim 10, wherein forming said compressively stressed silicon nitride material comprises depositing a silicon nitride layer above said transistor and patterning said silicon nitride layer to form a sidewall spacer in said gate electrode structure.

18. The method of claim 10, wherein forming said compressively stressed silicon nitride material comprises depositing a silicon nitride layer above metal silicide regions of said transistor.

19. The method of claim 18, further comprising forming a dielectric layer above said silicon nitride layer and patterning said dielectric layer using said silicon nitride layer as an etch stop layer.
